(19) United States
(12) Patent Application Publication
(10) Pub. No.: US 2021/0358724 A1
(43) Pub. Date: Nov. 18, 2021

(54) SiC MEMBER AND MANUFACTURING METHOD THEREOF

(71) Applicant: FERROTEC MATERIAL TECHNOLOGIES CORPORATION, Tokyo (JP)

(72) Inventor: Shogo TSUNAGI, Tamano-shi (JP)

(73) Assignee: ADMAP INC., Tamano-shi, Okayama (JP)

(21) Appl. No.: 16/488,357

(22) PCT Filed: Mar. 28, 2019
(86) PCT No.: PCT/JP2019/013822

§ 371 Date: Aug. 23, 2019

(30) Foreign Application Priority Data
Jun. 27, 2018 (JP) 2018-121517

(51) Int. Cl. H01J 37/32; C23C 16/32; C23C 16/56; C23C 16/00

(52) U.S. Cl. CPC H01J 37/32642; C23C 16/325; H01J 2237/334; C23C 16/006; C23C 16/56

(57) ABSTRACT

A technology secures favorable appearance of an SiC member. The SiC member includes: an SiC substrate having a front face and a back face; and a first SiC coat provided on the front face of the SiC substrate. The SiC substrate has first polycrystalline layers and second polycrystalline layers stacked alternately across a plurality of layers as polycrystalline layers having film properties different from each other. At least one of the first polycrystalline layers and at least one of the second polycrystalline layers appear on the front face. The first SiC coat is a polycrystalline layer having the same film property as that of any one of the first polycrystalline layer and the second polycrystalline layer.

### FIELD OF THE INVENTION

The present invention relates to an SiC member containing SiC and a manufacturing method thereof.

### BACKGROUND OF THE INVENTION

An SiC member containing silicon carbide (SiC) has excellent properties such as high durability, high acid resistance, and low specific resistance, and is widely used as a component for a semiconductor manufacturing apparatus. For example, Patent Documents 1 and 2 discuss techniques of using the SiC member as an etcher ring or an electrode in a plasma etching apparatus.

### CITATION LIST

### Patent Documents

Patent Document 1: Japanese Unexamined Patent Application Publication No. 2015-000836

Patent Document 2: Japanese Unexamined Patent Application Publication No. 2008-252045

### SUMMARY OF THE INVENTION

In the semiconductor manufacturing apparatus, a product defect may occur in a wafer due to even a slight processing variation. In addition, since the semiconductor manufacturing apparatus is used to treat a large number of wafers in a factory, a problem of the product defect of the wafer may spread to a large number of wafers without limiting to only a single wafer. Therefore, a user of the semiconductor manufacturing apparatus strictly controls the quality of the semiconductor manufacturing apparatus and components used therefor. The SiC member used in the semiconductor manufacturing apparatus requires a strict specification such as high durability and high purity. For this reason, the CVD-SiC formed through chemical vapor deposition (CVD), which has superior physical and chemical properties to those of sintered SiC, is used as the SiC in some cases. However, the CVD-SiC may form a pattern derived from a crystal structure or a layer structure on the surface of the SiC member in some cases. Such a pattern impairs appearance as a product, and in some cases, may concern the user of the semiconductor manufacturing apparatus.

In view of such problems, the present invention provides a technology for securing favorable appearance of the SiC member.

In order to address the aforementioned problems, according to the first aspect of the invention, there is provided an SiC member including: an SiC substrate having a front face and a back face; and a first SiC coat provided on the front face of the SiC substrate, wherein the SiC substrate has first polycrystalline layers and second polycrystalline layers stacked alternately across a plurality of layers as polycrystalline layers having film properties different from each other, at least one of the first polycrystalline layers and at least one of the second polycrystalline layers appear on the front face, and the first SiC coat is a polycrystalline layer having a film property similar to that of any one of the first polycrystalline layer and the second polycrystalline layer or a film property different from any of the first polycrystalline layer and the second polycrystalline layer.

In this aspect, since the first SiC coat is provided on the front face of the SiC substrate, it is possible to secure favorable appearance of the SiC member. Specifically, the SiC substrate includes the first polycrystalline layer and the second polycrystalline layer appearing on the front face. The first polycrystalline layer and the second polycrystalline layer form a pattern caused by a difference of the film property on the front face of the SiC substrate in some cases. Meanwhile, the first SiC coat has the same film property as that of any one of the first polycrystalline layer and the second polycrystalline layer or a film property different from any of the first polycrystalline layer and the second polycrystalline layer. That is, since the first SiC coat has a uniform film property, they do not form a pattern caused by the difference of the film property on the front face. Therefore, the pattern does not appear on the front face of the SiC member, and it is possible to secure favorable appearance of the SiC member.

According to the second aspect, it is conceivable that the first SiC coat has a specific resistance smaller than that of the SiC substrate.

The specific resistance of the entire SiC member is determined to a certain value as a user's requirement of the semiconductor manufacturing apparatus in some cases. In the second aspect, it is possible to appropriately adjust the specific resistance of the entire SiC member by appropriately adjusting the film thicknesses of the first SiC coat and the SiC substrate. As a result, it is possible to set the specific resistance of the entire SiC member to satisfy the user's requirement.

Since the SiC member is repeatedly used, the first polycrystalline layer and the second polycrystalline layer appearing on the front face of the SiC substrate may affect a crystal structure of the first SiC coat, so that the front face of the first SiC coat may be influenced.

For this reason, according to the third aspect, it is conceivable that the second polycrystalline layer has a film thickness larger than that of the first polycrystalline layer, and the first SiC coat has a film thickness larger than that of the first polycrystalline layer.

In this aspect, since the film thickness of the first SiC coat is at least larger than the first polycrystalline layer, it is possible to reduce a possibility that the front face of the first SiC coat is affected by the first polycrystalline layer and the second polycrystalline layer.

Note that, since a plurality of the first polycrystalline layers are provided, each of the first polycrystalline layers may have different film thicknesses. This similarly applies to the second polycrystalline layer. In addition, the first SiC coat, the first polycrystalline layer, and the second polycrystalline layer may have different film thicknesses depending on places. Herein, it is assumed that the film thickness refers to a film thickness in a representative place or an average of the film thicknesses in a plurality of representative places.

The deposition rate of the first polycrystalline layer may be slower than the deposition rate of the second polycrystalline layer. As a result, the first polycrystalline layer may become denser than the second polycrystalline layer.

In this regard, according to the fourth aspect, it is conceivable that the first SiC coat has a film property similar to that of the first polycrystalline layer, and the first polycrystalline layer has a film thickness smaller than that of the second polycrystalline layer.

According to this aspect, since the second polycrystalline layer has a large film thickness, it is possible to reduce a manufacturing time of the SiC substrate. In addition, since the first SiC coat has the same film property as that of the first polycrystalline layer, it is possible to densify the outer surface of the SiC member.

Note that the difference of the film property between the first polycrystalline layer and the second polycrystalline layer may include those described below.

According to the fifth aspect, each of the first polycrystalline layer and the second polycrystalline layer contains a plurality of crystal grains, and has an average grain size different depending on a difference of the film property.

According to the sixth aspect, the first polycrystalline layer and the second polycrystalline layer are formed as polycrystalline layers having colors different depending on the difference of the film property.

Note that, for convenience purposes, the average grain size may be set to a suitable value. The suitable average grain size may be obtained from an electron micrograph of the cross section of the SiC member. For example, a plurality of crystal grains having the representative size are selected from the polycrystalline layer appearing on the electron micrograph. The particle diameters of the selected crystal grains are measured. An average of the obtained particle diameters is regarded as a suitable average grain size.

The colors of the polycrystalline layers are different depending on the film property in some cases. In the case of chromatic color, the color is specified by three elements of chromaticity, saturation, and brightness. In the case of achromatic color, the color is specified by only the brightness. The color of the polycrystalline layer may be obtained from an electron micrograph of the cross section of the SiC member. Since the electron micrograph is typically expressed in grayscale, the color of the polycrystalline layer becomes achromatic. Therefore, in this case, each color of the first polycrystalline layer and the second polycrystalline layer is specified only by the brightness.

According to the seventh aspect, it is conceivable that at least one of the first polycrystalline layers and at least one of the second polycrystalline layers obliquely intersect the front face.

Specifically, a normal direction of the first polycrystalline layer and a normal direction of the second crystal layer have an angle range of 0° to 90° with respect to a normal direction of the front face of the SiC substrate. Note that this angle may be smaller than 45°, 30°, or 15° in some cases.

According to the eighth aspect, it is conceivable that the SiC member further includes a second SiC coat provided on the back face of the SiC substrate, at least one of the first polycrystalline layers and at least one of the second polycrystalline layers appear on the back face, and the second SiC coat is a polycrystalline layer having a film property similar to that of the first SiC coat.

According to this aspect, since the second SiC coat is provided on the back face of the SiC substrate, it is possible to secure favorable appearance of the SiC member. The principle thereof is similar to that of the case where the first SiC coat is provided on the front face of the SiC substrate.

According to the ninth aspect, it is conceivable that the SiC member is an etcher ring.

The etcher ring refers to a ring-shaped component used in plasma etching. Such a component includes, for example, a focus ring. The focus ring has an upper surface, a lower surface, an inner circumferential surface, and an outer circumferential surface, and is a component for holding an etching target wafer in a chamber.

According to the tenth aspect, it is conceivable that the SiC substrate and the first SiC coat are formed of CVD-SiC.

The CVD-SiC refers to SiC formed through chemical vapor deposition. The CVD-SiC has physical and chemical properties superior to those of the sintered SiC. The sintered SiC refers to SiC formed through sintering. In this aspect, it is possible to obtain an SiC member having excellent physical and chemical properties. Therefore, it is possible to prevent particles that may be generated, for example, when the SiC member is used in a plasma etching apparatus.

According to the eleventh aspect, there is provided a manufacturing method of an SiC member, including: forming an SiC substrate having a front face and a back face and having first polycrystalline layers and second polycrystalline layers stacked alternately across a plurality of layers as polycrystalline layers having film properties different from each other, at least one of the first polycrystalline layers and at least one of the second polycrystalline layers appearing on the front face; and forming a first SiC coat on the front face of the SiC substrate, the first SiC coat being a polycrystalline layer having a film property similar to that of any one of the first polycrystalline layer and the second polycrystalline layer.

In this aspect, it is possible to obtain the SiC member of the first aspect.

According to the twelfth aspect, there is provided an SiC member including: an SiC substrate having a front face and a back face; and a first SiC coat provided on the front face of the SiC substrate, wherein the SiC substrate has first polycrystalline layers and second polycrystalline layers stacked alternately across a plurality of layers as polycrystalline layers having film properties different from each other, the first SiC coat is a polycrystalline layer having a film property similar to that of any one of the first polycrystalline layer and the second polycrystalline layer, and the first SiC coat has a specific resistance smaller than that of the SiC substrate.

In this aspect, it is possible to appropriately adjust the specific resistance of the entire SiC member to a wide adjustment range.

### BRIEF DESCRIPTION OF DRAWINGS

FIG. 1 is a plan view illustrating a front face of an etcher ring;

FIG. 2 is a cross-sectional view taken along a line A-A of the plan view of the etcher ring;

FIG. 3 is a partial enlarged view illustrating a portion B in the A-A cross-sectional view of the etcher ring;

FIG. 4 is an enlarged plan view illustrating a front face of a SiC substrate corresponding to a portion C in the plan view of the etcher ring;

FIG. 5 is an enlarged plan view illustrating a back face of the SiC substrate corresponding to the portion C in the plan view of the etcher ring;

FIG. 6 is a diagram illustrating a cross-sectional photograph of the etcher ring;

FIG. 7 is a diagram illustrating a cross-sectional photograph of the SiC substrate;

FIG. 8 is a diagram illustrating a photograph of the front face of the SiC substrate;

FIG. 9 is a diagram illustrating a photograph of the back face of the SiC substrate;

FIG. 10 is a diagram illustrating a manufacturing process of the etcher ring;

FIG. 11 is a diagram illustrating a manufacturing process of the etcher ring;

FIG. 12 is a diagram illustrating a manufacturing process of the etcher ring; and

FIG. 13 is a diagram illustrating a relationship between a deposition rate and a specific resistance of CVD-SiC.

### DESCRIPTION OF EMBODIMENTS

Embodiments of the present invention will now be described with reference to the accompanying drawings.

(1) General Configuration

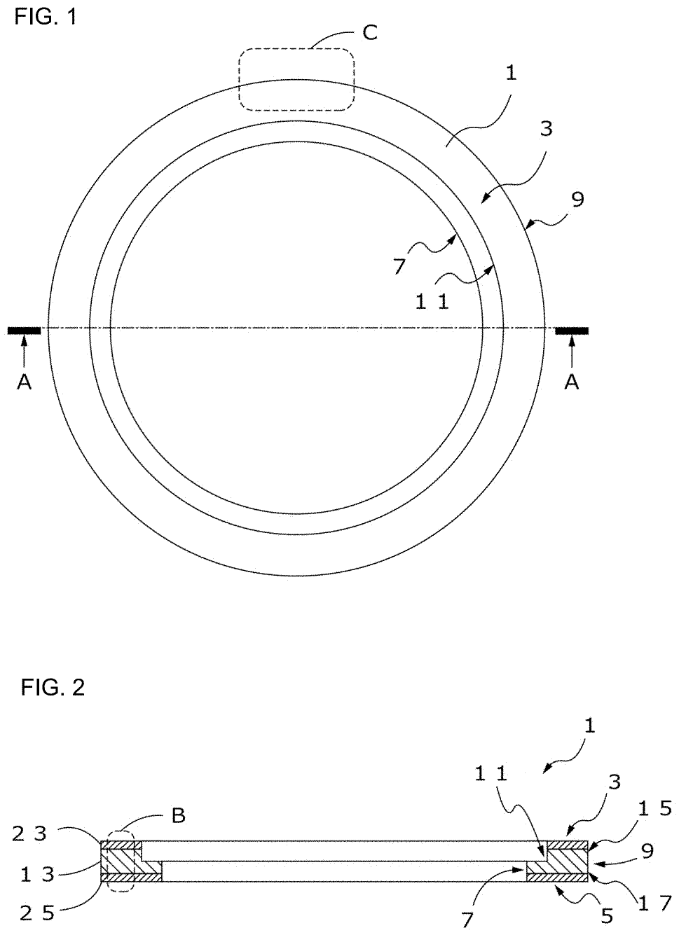

As illustrated in FIGS. 1 and 2, an etcher ring 1 includes an SiC substrate 13 having a front face 15 and a back face 17, a first SiC coat 23 provided on the front face 15 of the SiC substrate 13, and a second SiC coat 25 provided on the back face 17 of the SiC substrate 13. The etcher ring 1 has a front face 3, a back face 5, an inner circumferential surface 7 interposed between the front face 3 and the back face 5, and an outer circumferential surface 9 interposed between the front face 3 and the back face 5. The etcher ring 1 has a step portion 11 formed in an annular shape. A wafer as an etching target is placed on this step portion 11.

All of the SiC substrate 13, the first SiC coat 23, and the second SiC coat 25 are formed of CVD-SiC.

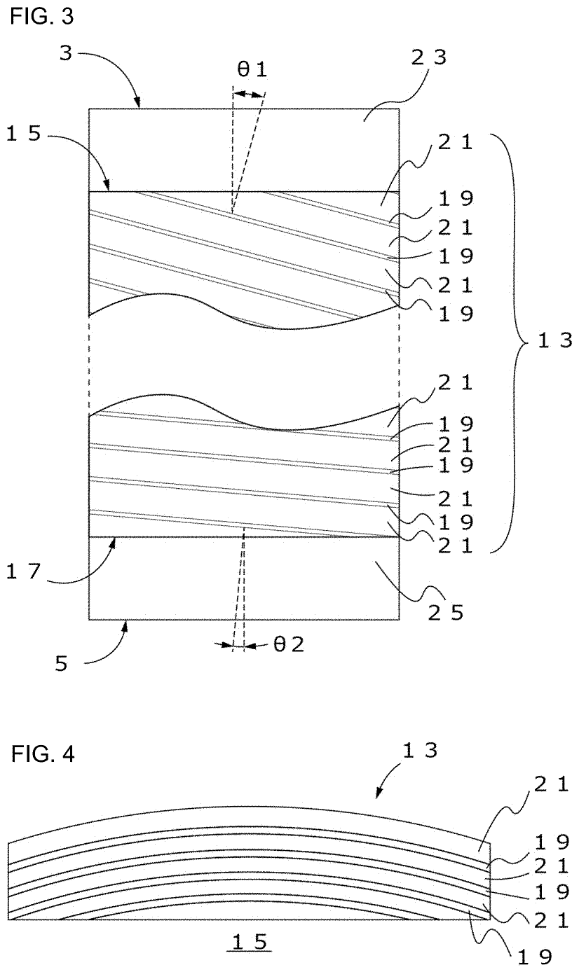

As illustrated in FIG. 3, the SiC substrate 13 includes first polycrystalline layers 19 and second polycrystalline layers 21 stacked alternately across multiple layers as polycrystalline layers having different film properties. The first polycrystalline layers 19 and the second polycrystalline layers 21 are formed of the same material, that is, CVD-SiC. However, the first polycrystalline layers 19 and the second polycrystalline layers 21 are formed as polycrystalline layers having different film properties in a film formation process described below.

As illustrated in FIG. 3, at least one of the first polycrystalline layers 19 and at least one of the second polycrystalline layers 21 obliquely intersect the front face 15 of the SiC substrate 13. As a result, at least one of the first polycrystalline layers 19 and at least one of the second polycrystalline layers 21 appear on the front face 15 of the SiC substrate 13. Similarly, at least one of the first polycrystalline layers 19 and at least one of the second polycrystalline layers 21 obliquely intersect the back face 17 of the SiC substrate 13. As a result, at least one of the first polycrystalline layers 19 and at least one of the second polycrystalline layers 21 appear on the back face 17 of the SiC substrate 13.

The first SiC coat 23 has the same film property as that of any one of the first polycrystalline layer 19 and the second polycrystalline layer 21 or a film property different from that of any of the first polycrystalline layer 19 and the second polycrystalline layer 21. In addition, the second SiC coat 25 has the same film property as that of the first SiC coat 23 or a film property different from that of any of the first polycrystalline layer 19 and the second polycrystalline layer 21. According to this embodiment, the first SiC coat 23 and the second SiC coat 25 have the same film property as that of the first polycrystalline layer 19.

The second polycrystalline layer 21 has a film thickness larger than that of the first polycrystalline layer 19. The first SiC coat 23 has a film thickness larger than that of the first polycrystalline layer 19. Similarly, the second SiC coat 25 has a film thickness larger than that of the first polycrystalline layer 19.

The second SiC coat 25 may have the same film thickness as that of the first SiC coat 23. As described below, according to this embodiment, the first SiC coat 23 and the second SiC coat 25 are formed through the same process. By forming the first SiC coat 23 and the second SiC coat 25 with the same film thickness, it is possible to efficiently use the SiC material.

Both the first SiC coat 23 and the second SiC coat 25 may have film thicknesses smaller than that of the SiC substrate 13. Conversely, both the first SiC coat 23 and the second SiC coat 25 may have film thicknesses larger than that of the SiC substrate 13.

As illustrated in FIG. 3, the front face 15 of the SiC substrate 13 is substantially parallel to the back face 17. The first polycrystalline layer 19 and the second polycrystalline layer 21 intersect the front face 15 at an angle θ1. The angle θ1 is, for example, larger than 0° and smaller than 15°. In addition, the first polycrystalline layer 19 and the second polycrystalline layer 21 intersect the back face 17 at an angle θ2. The angle θ2 is also, for example, larger than 0° and smaller than 15°. According to this embodiment, the angle θ1 is different from the angle θ2. More specifically, the angle θ1 is larger than the angle θ2. However, without limiting thereto, the angle θ1 may be equal to the angle θ2 or may be smaller than the angle θ2. Note that the angles θ1 and θ2 may differ depending on a position of the etcher ring 1 in a radial direction. In order to compare the angles θ1 and θ2, it is assumed that the angles are measured in substantially the same position in the radial direction.

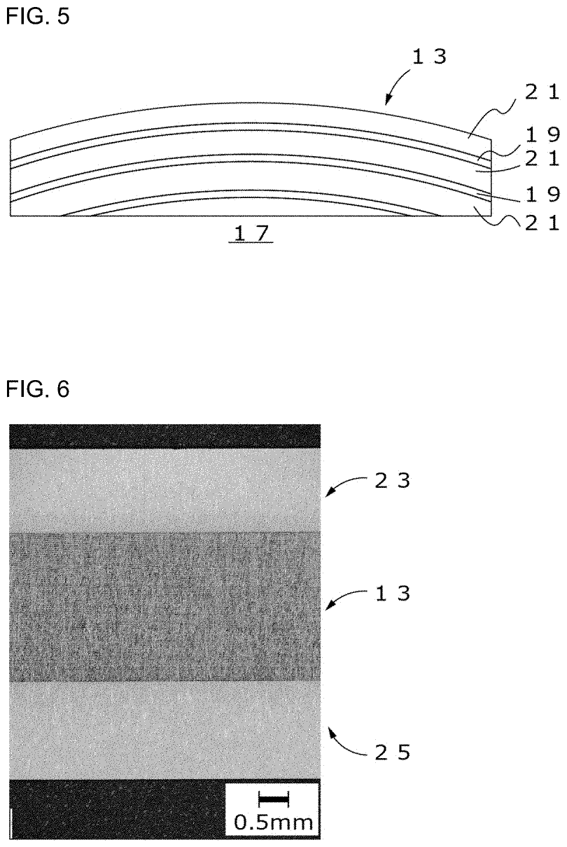

As illustrated in FIGS. 4 and 5, the front face 15 and the back face 17 of the SiC substrate 13 have annular stripe patterns derived from the first polycrystalline layer 19 and the second polycrystalline layer 21 appearing on the front face 15 and the back face 17, respectively. On the front face 15, a concentric stripe pattern having a pitch corresponding to the angle θ1 appears. On the back face 17, a concentric stripe pattern having a pitch corresponding to the angle θ2 appears.

The difference of the film property between the first polycrystalline layer 19 and the second polycrystalline layer 21 appears as a color difference in appearance. That is, the first polycrystalline layer 19 and the second polycrystalline layer 21 are formed as polycrystalline layers having colors different depending on the film property. Although the CVD-SiC exhibits different colors depending on film formation parameters such as a source gas concentration, a temperature, and a deposition rate, it generally exhibits a gray-based color. In the case of the gray-based color, the color difference appears as a brightness difference. As shown in the appearance photographs of FIGS. 8 and 9, both the front face 15 and the back face 17 of the SiC substrate 13 have an annular stripe pattern having light gray and dark gray colors.

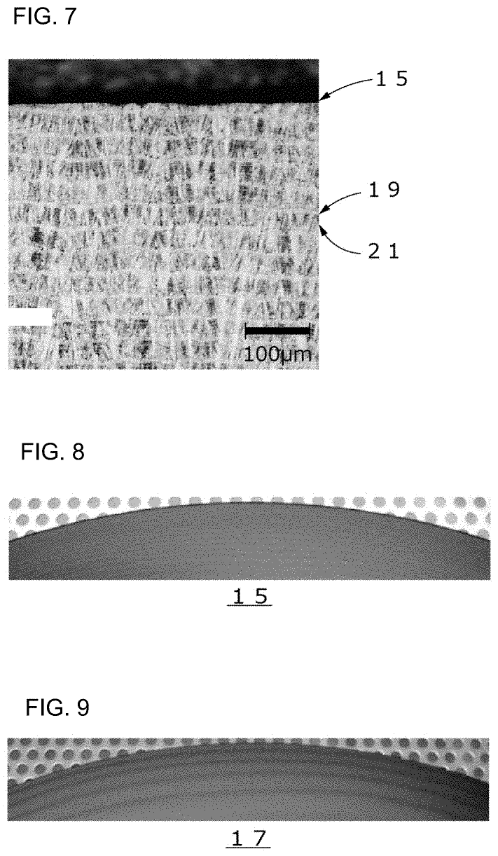

The difference of the film property between the first polycrystalline layer 19 and the second polycrystalline layer 21 also appears as a color difference in the electron micrograph of the cross section of the SiC substrate 13. Since the electron micrograph is expressed in grayscale, the color difference appears as a brightness difference. As illustrated in the electron micrographs of FIGS. 6 and 7, the SiC substrate 13 has a multilayered structure including light gray and dark gray colors. The electron micrographs are obtained in the following procedure. First, the SiC substrate 13 is cut along the radial direction of the etcher ring 1. Then, the cut face of the SiC substrate 13 is etched to expose crystal grains of the polycrystalline layers on the cut face. Then, the cut face is observed using an electron microscope.

As illustrated in the electron micrographs of FIGS. 6 and 7, each of the first polycrystalline layer 19 and the second polycrystalline layer 21 has different brightness. In an electron micrograph of polycrystals including a plurality of crystal grains, the brightness difference indicates a difference in an average grain size. That is, each of the first polycrystalline layer 19 and the second polycrystalline layer 21 contains a plurality of crystal grains and has an average grain size different depending on the difference of the film property.

In the case of plasma etching, the etcher ring 1 is electrically charged by receiving electric charges from plasma. If the etcher ring 1 is excessively charged, a discharge from the etcher ring 1 to the wafer may occur, so that the wafer may be defected. In order to prevent such a defect, the etcher ring 1 is required to have an appropriate specific resistance for discharging the charges of the etcher ring 1 to the ground. According to this embodiment, the first SiC coat 23 and the second SiC coat 25 have specific resistances different from that of the SiC substrate 13. Specifically, the first SiC coat 23 and the second SiC coat 25 have specific resistances smaller than that of the SiC substrate 13. As a result, it is possible to obtain an etcher ring 1 having a desired specific resistance by appropriately adjusting the film thicknesses of the first SiC coat 23, the second SiC coat 25, and the SiC substrate 13.

Specifically, the specific resistance of the etcher ring 1 is determined by the respective specific resistances and film thicknesses of the first SiC coat 23, the second SiC coat 25, and the SiC substrate 13 as described below.

R=(R₁×T₁/T)+(R₂×T₂/T)+(R₃×T₃/T)

Here, “R” and “T” denotes a specific resistance and a film thickness, respectively, of the etcher ring 1. “R₁” and T₁” denotes a specific resistance and a film thickness, respectively, of the first SiC coat 23. “R₂” and T₂” denotes a specific resistance and a film thickness, respectively, of the second SiC coat 25. “R₃” and T₃” denotes a specific resistance and a film thickness, respectively, of the SiC substrate 13. The specific resistance R and the film thickness T are determined by the requirement. The specific resistances R₁, R₂, and R₃ are determined depending on the film properties suitable for the first SiC coat 23, the second SiC coat 25, and the SiC substrate 13, respectively. The film thicknesses T₁, T₂, and T₃ can be arbitrarily adjusted. Therefore, it is possible to obtain any specific resistance R by adjusting the film thicknesses T₁, T₂, and T₃.

(2) Manufacturing Method

The etcher ring 1 may be manufactured as follows. First, the SiC substrate 43 is formed. This SiC substrate 43 has the front face 15 and the back face 17, and includes the first polycrystalline layers 19 and the second polycrystalline layers 21 stacked alternately across a plurality of layers as polycrystalline layers having different film properties. At least one of the first polycrystalline layers 19 and at least one of the second polycrystalline layers 21 appear on the front face 15.

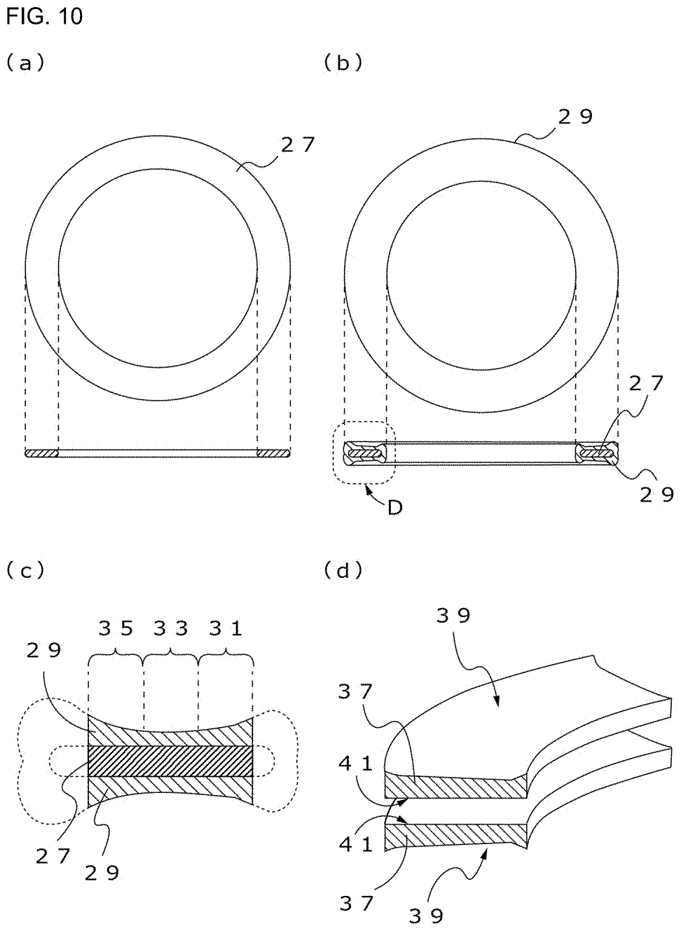

For this purpose, an annular graphite substrate 27 is prepared as illustrated in FIG. 10(a). Then, as illustrated in FIG. 10(b), a CVD-SiC film 29 that entirely covers the graphite substrate 27 is formed. The CVD-SiC film 29 is formed, for example, using a CVD apparatus illustrated in FIG. 12(a). The graphite substrate 27 is rotatably supported inside a chamber 47 of the CVD apparatus. The source gas 53 is supplied from a supply port 49 into the chamber 47 and is discharged from an outlet port 51 to the outside of the chamber 47. The source gas 53 generates a chemical reaction inside the chamber 47 to produce SiC. The produced SiC is deposited on the graphite substrate 27 to form the CVD-SiC film 29. Since the source gas 53 is consumed from time to time depending on the chemical reaction, the chamber 47 forms a concentration gradient of the source gas 53 gradually increasing from the outlet port 51 to the supply port 49. Simply to say, the chamber 47 has a first region 55 containing the source gas 53 having a first concentration and a second region 57 containing the source gas 53 having a second concentration different from the first concentration. The graphite substrate 27 is rotated by an external motor, so that any part of the graphite substrate 27 alternately passes through the first region 55 and the second region 57 evenly. As a result, it is possible to secure uniformity in the film property and the film thickness along the circumferential direction of the CVD-SiC film 29.

Then, as illustrated in FIG. 10(c), the CVD-SiC film 29 is partially removed to expose the graphite substrate 27. FIG. 10(c) is an enlarged view illustrating the part D of FIG. 10(b). The CVD-SiC film 29 has an inner circumferential portion 31, a center portion 33, and an outer circumferential portion 35. The inner circumferential portion 31, the center portion 33, and the outer circumferential portion 35 have crystal growth rates different from each other. Specifically, the center portion 33 has a crystal growth rate slower than those of the outer circumferential portion 35 and the inner circumferential portion 31. For this reason, the center portion 33 has a film thickness smaller than those of the outer circumferential portion 35 and the inner circumferential portion 31.

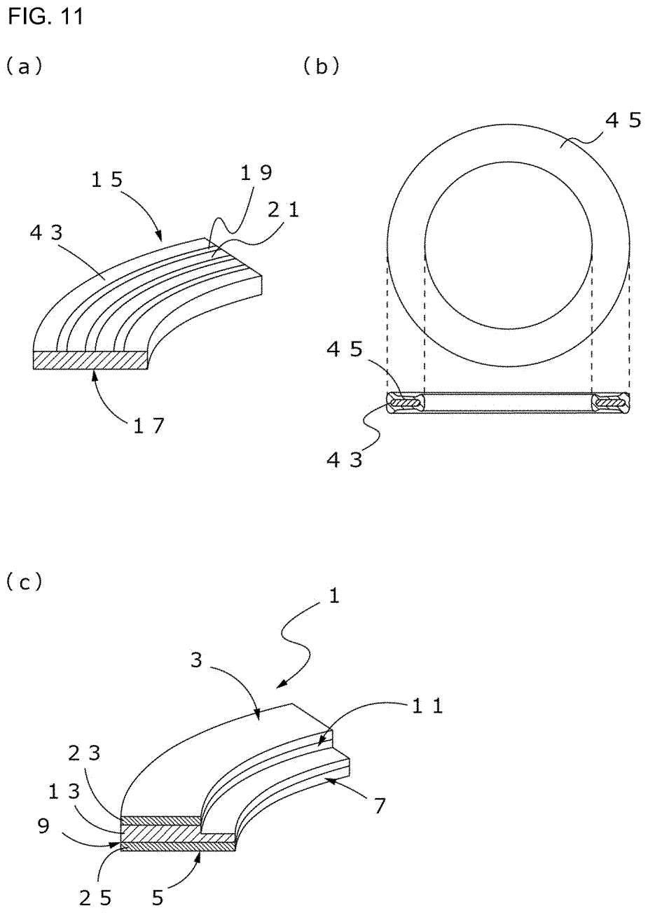

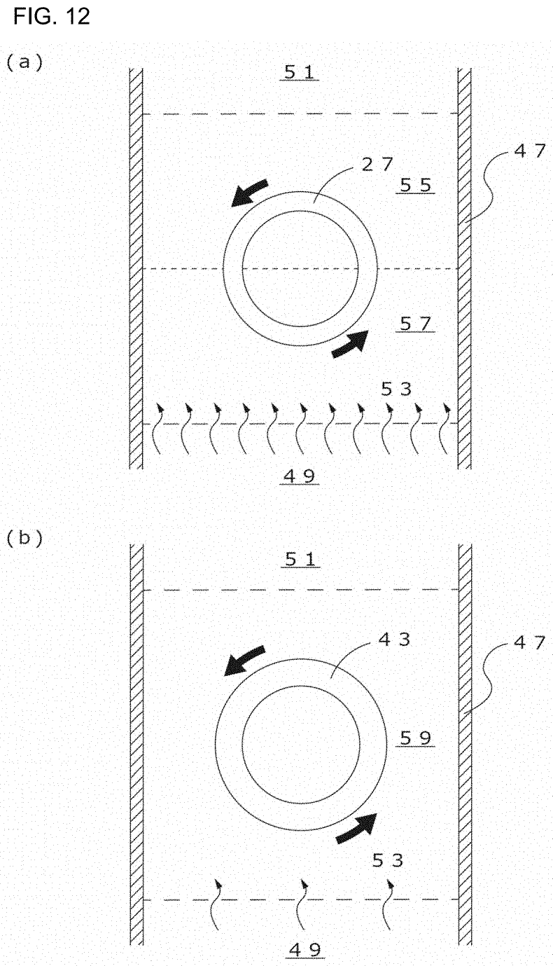

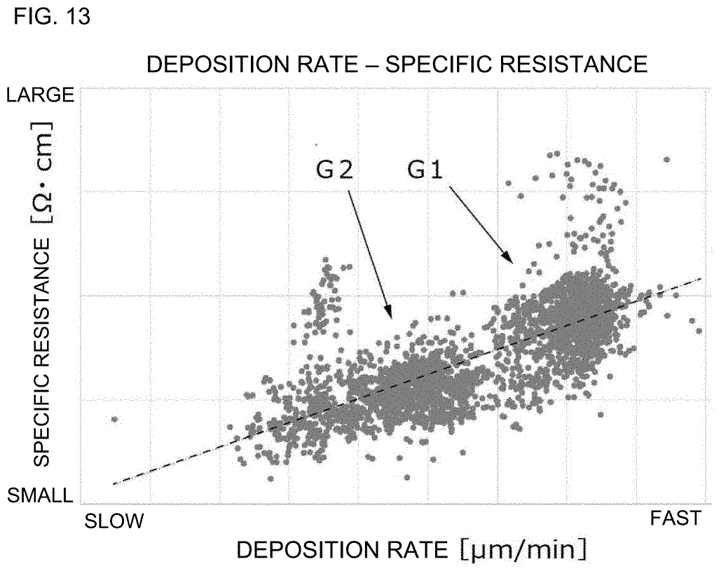

Then, as illustrated in FIG. 10(d), the graphite substrate 27 is removed to obtain two annular multilayered SiC blocks 37. The multilayered SiC block 37 has a curved front face 39 and a flat back face 41. The front face 39 and the back face 41 of the multilayered SiC block 37 are planarized by grinding. As a result, as illustrated in FIG. 11(a), it is possible to obtain the SiC substrate 43 having the front face 15 and the back face 17.

As described above, the CVD-SiC film 29 is formed while alternately passing through the first region 55 and the second region 57 inside the chamber 47. In the first region 55, the first polycrystalline layer 19 is formed. In the second region 57, the second polycrystalline layer 21 is formed. That is, a process of forming the first polycrystalline layer 19 in the first region 55 containing the source gas 53 having the first concentration and a process of forming the second polycrystalline layer 21 in the second region 57 containing the source gas 53 having the second concentration different from the first concentration are alternately repeated. For this reason, the CVD-SiC film 29 has a multilayered structure in which the first polycrystalline layers 19 and the second polycrystalline layers 21 are alternately stacked. Furthermore, as described above, the crystal growth rate of the CVD-SiC film 29 is different between the inner circumferential portion 31, the center portion 33, and the outer circumferential portion 35. That is, both the first polycrystalline layer 19 and the second polycrystalline layer 21 have film thicknesses different between the inner circumferential portion 31, the center portion 33, and the outer circumferential portion 35. The SiC substrate 43 is obtained by being cut out from such a multilayered SiC block 37. That is, the front face 15 and the back face 17 of the SiC substrate 43 are formed by processing the front face 39 and the back face 41 of the multilayered SiC block 37. Therefore, as illustrated in FIG. 11(a), the first polycrystalline layer 19 and the second polycrystalline layer 21 appear on the front face 15 of the SiC substrate 43. Similarly, the first polycrystalline layer 19 and the second polycrystalline layer 21 also appear on the back face 17 of the SiC substrate 43. However, as illustrated in FIGS. 4 and 5, the stripe patterns differ between the front face 15 and the back face 17 of the SiC substrate 43.

The first SiC coat 23 as a polycrystalline layer having the same film property as that of any one of the first polycrystalline layer 19 and the second polycrystalline layer 21 is formed on the front face 15 of the SiC substrate 43. In addition, the second SiC coat 25 as a polycrystalline layer having the same film property as that of the first SiC coat 23 is formed on the back face 17 of the SiC substrate 43.

For this purpose, as illustrated in FIG. 11(b), a CVD-SiC film 45 that entirely covers the SiC substrate 43 is formed. The CVD-SiC film 45 is formed, for example, using the CVD apparatus as illustrated in FIG. 12(b). The SiC substrate 43 is rotated by a motor in the chamber 47 of the CVD apparatus. The CVD-SiC film 45 is formed in a third region 59 containing the source gas 53 having a third concentration, which is equal to any one of the first concentration and the second concentration. According to this embodiment, the third concentration is equal to the first concentration. In this case, since the concentration of the source gas 53 inside the chamber 47 is relatively low, the concentration gradient in the chamber 47 is relatively small and ignorable. For this reason, the CVD-SiC film 45 has a generally even film property, that is, a uniform film property.

Then, the etcher ring 1 is formed by processing the SiC substrate 43 and the CVD-SiC film 45 as illustrated in FIG. 11(c).

(3) Modifications

Needless to say, various forms may be possible within the technical scope of the invention without limiting the embodiments of the invention to the aforementioned examples.

For example, in the aforementioned embodiment, an annular member having an opening in the center, such as the etcher ring 1, has been exemplified as the SiC member. However, the shape of the SiC member is not limited to the annular shape, and a disc member having no opening in the center may also be employed. Furthermore, without limiting to the circular shape, a polygonal shape may also be employed.

(4) Advantages and Effects

In this configuration, since the first SiC coat 23 is provided on the front face 15 of the SiC substrate 13, it is possible to secure favorable appearance of the SiC member. Specifically, the SiC substrate 13 includes the first polycrystalline layer 19 and the second polycrystalline layer 21 appearing on the front face, respectively. The first polycrystalline layer 19 and the second polycrystalline layer 21 form patterns having different film properties on the front face 15 of the SiC substrate 13 in some cases. On the other hand, the first SiC coat 23 has the same film property as that of any one of the first polycrystalline layer 19 and the second polycrystalline layer 21. That is, since the first SiC coat 23 has a uniform film property, it does not form a pattern caused by different film properties on the front face thereof. Therefore, no pattern appears on the front face of the SiC member, and it is possible to secure favorable appearance of the SiC member.

In the aforementioned configuration, since the second SiC coat 25 is provided on the back face 17 of the SiC substrate 13, it is possible to secure favorable appearance of the SiC member.

In the aforementioned configuration, since a certain level of film thickness is secured for the first SiC coat 23, it is possible to reduce a possibility that the front face of the first SiC coat 23 is influenced by the first polycrystalline layer 19 and the second polycrystalline layer 21.

In the aforementioned configuration, it is possible to appropriately adjust the specific resistance of the entire SiC member by appropriately adjusting the film thicknesses of the first SiC coat 23 and the SiC substrate 13. As a result, it is possible to satisfy a user's requirement for the specific resistance of the entire SiC member.

Note that the specific resistance of the CVD-SiC has a meaningful relationship with the deposition rate thereof as illustrated in FIG. 17. A data group G1 refers to a set of data regarding the CVD-SiC formed under an environment of the source gas 53 having a relatively high concentration. Similar to the SiC substrate 13, this CVD-SiC has a multilayered structure in which the first polycrystalline layers 19 and the second polycrystalline layers 21 having different film properties are alternately stacked. A data group G2 refers to a set of data regarding the CVD-SiC formed under an environment of the source gas 53 having a relatively low concentration. Similar to the first SiC coat 23 and the second SiC coat 25, this CVD-SiC has a uniform film property.

If only the CVD-SiC indicated by the data group G2 is employed to manufacture the SiC member, it takes a lot of time in manufacturing. Conversely, if only the CVD-SiC indicated by the data group G1 is employed, a stripe pattern appears on the front or back face of the SiC member. In this regard, in the aforementioned configuration, the CVD-SiC indicated by the data group G1 is employed for the SiC substrate 13, and the CVD-SiC indicated by the data group G2 is employed for the first SiC coat 23 and the second SiC coat 25. As a result, it is possible to reduce a manufacturing time and obtain favorable appearance.

If only one of the data groups G2 and G1 is employed to manufacture the SiC member, design freedom for the specific resistance of the entire SiC member is narrowed. In the aforementioned configuration, the CVD-SiC indicated by the data group G1 is employed for the SiC substrate 13, and the CVD-SiC indicated by the data group G2 is employed for the first SiC coat 23 and the second SiC coat 25. As a result, it is possible to broaden the design freedom for the specific resistance of the entire SiC member.

### REFERENCE SIGNS LIST

1 etcher ring
13 SiC substrate
19 first polycrystalline layer
21 second polycrystalline layer
23 first SiC coat
25 second SiC coat

1. An SiC member comprising:
an SiC substrate having a front face and a back face; and
a first SiC coat provided on the front face of the SiC substrate,
wherein the SiC substrate has first polycrystalline layers and second polycrystalline layers stacked alternately across a plurality of layers as polycrystalline layers having film properties different from each other,
at least one of the first polycrystalline layers and at least one of the second polycrystalline layers appear on the front face, and
the first SiC coat is a polycrystalline layer having a film property similar to that of any one of the first polycrystalline layer and the second polycrystalline layer or a film property different from any of the first polycrystalline layer and the second polycrystalline layer.

2. The SiC member according to claim 1, wherein the first SiC coat has a specific resistance smaller than that of the SiC substrate.

3. The SiC member according to claim 1, wherein the second polycrystalline layer has a film thickness larger than that of the first polycrystalline layer, and
the first SiC coat has a film thickness larger than that of the first polycrystalline layer.

4. The SiC member according to claim 1, wherein the first SiC coat has a film property similar to that of the first polycrystalline layer, and
the first polycrystalline layer has a film thickness smaller than that of the second polycrystalline layer.

5. The SiC member according to claim 1, wherein each of the first polycrystalline layer and the second polycrystalline layer contains a plurality of crystal grains, and has an average grain size different depending on a difference of the film property.

6. The SiC member according to claim 1, wherein the first polycrystalline layer and the second polycrystalline layer are formed as polycrystalline layers having colors different depending on the difference of the film property.

7. The SiC member according to claim 1, wherein at least one of the first polycrystalline layers and at least one of the second polycrystalline layers obliquely intersect the front face.

8. The SiC member according to claim 1, further comprising a second SiC coat provided on the back face of the SiC substrate,
wherein at least one of the first polycrystalline layers and at least one of the second polycrystalline layers appear on the back face, and
the second SiC coat is a polycrystalline layer having a film property similar to that of the first SiC coat.

9. The SiC member according to claim 1, wherein the SiC member is an etcher ring.

10. The SiC member according to claim 1, wherein the SiC substrate and the first SiC coat are formed of CVD-SiC.

11. A manufacturing method of an SiC member, comprising:
forming an SiC substrate having a front face and a back face and having first polycrystalline layers and second polycrystalline layers stacked alternately across a plurality of layers as polycrystalline layers having film properties different from each other, at least one of the first polycrystalline layers and at least one of the second polycrystalline layers appearing on the front face; and
forming a first SiC coat on the front face of the SiC substrate, the first SiC coat being a polycrystalline layer having a film property similar to that of any one of the first polycrystalline layer and the second polycrystalline layer.
